(19) United States
(12) Patent Application Publication
(10) Pub. No.: US 2009/0093986 A1
(43) Pub. Date: Apr. 9, 2009

(54) Method and Apparatus for Elimination of Spurious Response due to Mixer Feed-Through

(75) Inventors: Francois LaMarche, New Milford, NJ (US); Laxmikant Joshi, Palo Alto, CA (US); Jonathan Libby, Gray, ME (US)

Correspondence Address: LECROY CORPORATION, 700 CHESTNUT RIDGE ROAD, CHESTNUT RIDGE, NY, 10977, US

(73) Assignee: LeCroy Corporation, Chestnut Ridge, NY (US)

(21) Appl. No.: 12/245,252

(22) Filed: Oct. 3, 2008

Related U.S. Application Data
(60) Provisional application No. 60/997,603, filed on Oct. 4, 2007.

(51) Int. Cl. G01R 23/00

(52) U.S. Cl. 702/106

(57) ABSTRACT

A method for correcting feed through signals for use with an oscilloscope employing Digital Bandwidth Interleaving is provided. The method comprises the steps of converting an original signal to a frequency other than an original frequency of the original signal, determining one or more feed through signals not converted with the original signal, providing an offsetting correction signal and combining the converted signal, the non-converted feed through signal, and the offsetting correction signal.

### BACKGROUND OF THE INVENTION

A digital bandwidth interleaving (DBI) oscilloscope (see, for example, U.S. Pat. Nos. 7,219,037; 7,139,684; 7,222,055; 7,058,548; 7,373,281; and U.S. patent application Ser. Nos. 11/525,345; 12/102,946; 12/112,218 the contents of these patents and applications being incorporated herein by reference) offers a remarkable solution for extending the bandwidth of oscilloscopes by allowing the high-frequency content of the acquired signal to be frequency shifted to a lower frequency range so that it can be acquired using channels that have a limited bandwidth. Hardware that has the specialized function of converting such higher frequency signals to a range of frequencies that are receivable by an existing digitizer technology typically use radio-frequency mixers surrounded by radio-frequency amplifiers and filters. Such a design has been demonstrated in several LeCroy® Corporation products employing a Digital Bandwidth Interleave method, such as the LeCroy® SDA11000 and LeCroy®SDA18000.

When employing such technology, it is often the case that the hardware used to digitize the frequency-shifted band will have a higher available bandwidth than the hardware used to digitize the lower frequency band. This is, for instance, because this hardware is freed from the burden of receiving the DC component of the signal, freed from having to protect against excessive DC components of the voltage, and freed from the requirement of a wide dynamic range.

When this is the case, and the bandwidth available on the channels that receive a shifted high frequency portion of the signal is larger than the bandwidth of the channel that receives the low frequency portion of the signal, one would want to use as much of the available bandwidth as possible. However, frequency-shifting hardware, such as double- or triple-balanced radio frequency mixers, generally allow some of the signal to propagate without being shifted/converted. This is known as RF-IF isolation. When the RF-IF isolation is not better than an SFDR specification of the oscilloscope individual channels, there may be a degradation of the specification of the oscilloscope with respect to the channels.

Therefore it would be beneficial to provide a solution to overcome this problem.

### SUMMARY OF THE INVENTION

In accordance with the invention, the inventors have determined that overcoming such a problem would allow for the use of a substantially greater portion of theoretically available bandwidth when employing a bandwidth interleaving system in an oscilloscope. It is the degradation of the oscilloscope channel specification which is minimized when the method and apparatus in accordance with the invention are employed.

In accordance with the invention, if BW_LF represents the bandwidth of the channel that receives the low-frequency portion of the signal input by the user of the DBI oscilloscope, and BW_HF represents the bandwidth of the channel that receives the first band of radio-frequencies under frequency-shifting DBI technology, the bandwidth spanned by these two bands together is theoretically as high as BW_LF+BW_HF, but practically somewhat less than the theoretical maximum. Such a maximum achievable bandwidth can be realized by using a mixer whose LO input is connected to a tone whose frequency is nearly BW_LF+BW_HF, or whose frequency is nearly BW_LF. Both schemes produce converted frequencies in this HF band that range from near 0 to near BW_HF.

The inventors of the present invention have determined that a problem arises in that feed-through allows certain frequencies f, specifically those higher than BW_LF, but smaller than BW_HF, to arrive unconverted in the HF-band channel. This happens irrespective of whether LO is near BW_LF+BW_HF or near BW_LF. Therefore, when the DBI software processing system associated with an oscilloscope processes the acquired waveform, this will result in a spur at frequency f_LO−f (in the first scheme) or a spur at frequency f_LO+f (in the second scheme).

In accordance with the present invention, the amount (amplitude-wise and phase-wise) of feed-through present for any specific input frequency can be calibrated in as much as it is reproducible, and, for a given signal, the feed-through contribution to the signal can then be substantially subtracted.

Still other objects and advantages of the invention will in part be obvious and will in part be apparent from the specification and the drawings.

The invention accordingly comprises the several steps and the relation of one or more of such steps with respect to each of the others, and the apparatus embodying features of construction, combination(s) of elements and arrangement of parts that are adapted to effect such steps, all as exemplified in the following detailed disclosure, and the scope of the invention will be indicated in the claims.

### BRIEF DESCRIPTION OF THE DRAWINGS

For a more complete understanding of the invention, reference is made to the following description and accompanying drawings, in which:

FIG. 1 is a flow chart diagram depicting a first embodiment of the invention employing a down-side down-conversion;

FIG. 2 is a flow chart diagram depicting a first embodiment of the invention employing an up-side down-conversion;

FIG. 3 is a flowchart diagram depicting signal flow in a known system design;

FIG. 4 is a flowchart diagram depicting signal flow in accordance with an embodiment of the invention;

FIG. 5 is a flowchart diagram representing a calibration algorithm in accordance with an embodiment of the present invention; and

FIG. 6 depicts a calibration scheme in accordance with an embodiment of the invention.

### DETAILED DESCRIPTION OF THE PREFERRED EMBODIMENTS

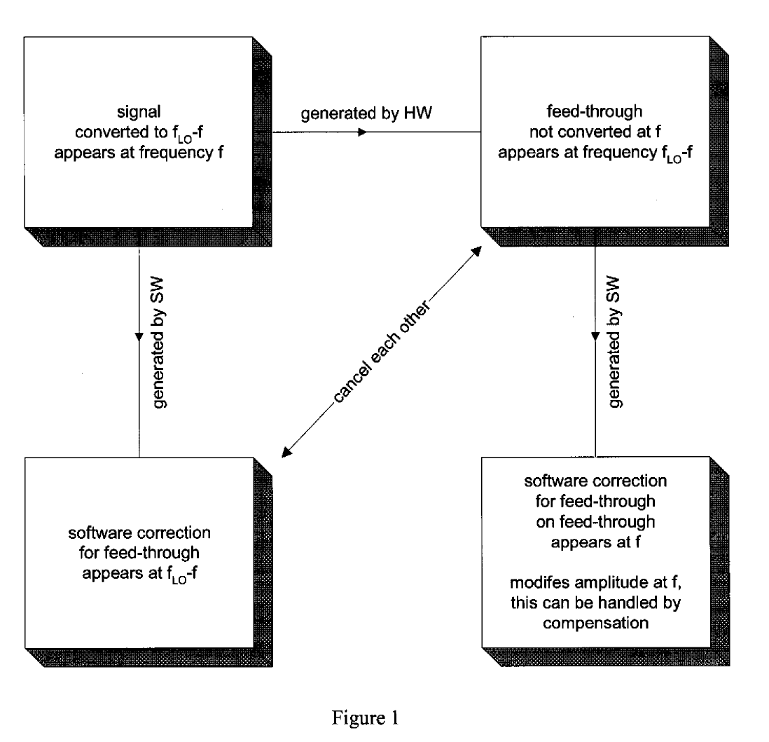

The invention will now be described making reference to the included Figures. Referring first to FIG. 1, a first case (down-side down-conversion) is shown. A signal of frequency f is first converted to f_{LO}−f but the oscilloscope processing software may result in the signal appearing at frequency f. During processing the hardware system of the oscilloscope feeds through a portion of the signal that is not converted at frequency f, and thus appears at frequency f_{LO}−f. In accordance with the invention, a software correction system is provided for correcting the feed-through that appears at frequency f_{LO}−f. As is shown in FIG. 1, this software correction is designed to offset the feed-through error generated by the hardware portion of the system. Therefore, in accordance with further operation of the software system of the oscilloscope, the software correction for the feed-through appears at frequency f_{LO}−f. While this correction will also change the amplitude of the signal at frequency f, appropriate further amplitude compensation is provided to overcome this issue.

In such a down-conversion situation, the down-converted and fed-through frequency ranges overlap. This means that some of the signal that gets subtracted by this correction should not have been subtracted; the reason is that some signal feeds through. While this feed-through can rightfully be subtracted, during such a feed-through software subtraction, because of the presence of this non-converted feed-through tone, it is difficult to distinguish this feed-through tone from a legitimate signal present in the acquired data. Since this second order effect is ultimately the subtraction of a tone at the original correct frequency, this causes a change of amplitude and phase of the original tone.

Thus, as noted above, in the context of an oscilloscope where DSP techniques allow frequency response compensation, this is a problem which is very easy to mitigate. In order for the correction of this feed-through to be possible, and for it not to cause excessive additional noise, it is a prerequisite that the feed-through be small compared with the signal to start with. A typical acceptable ratio of size between the feed-through and converted signal coming out of the mixer is 20 dB. Otherwise there is the risk of a near-cancellation of the original signal when subtracting the feed-through.

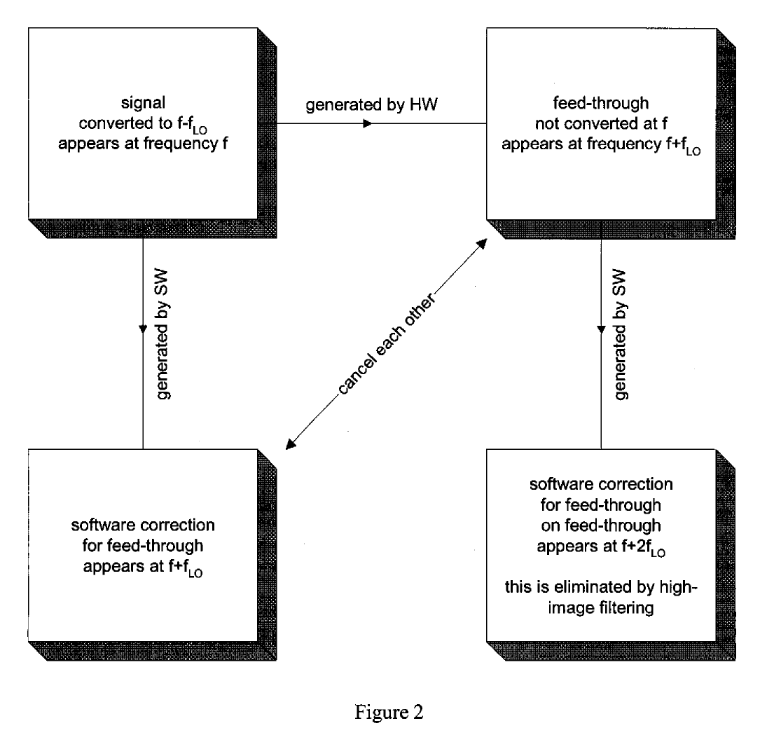

Referring next to FIG. 2, a second case is depicted, and comprises an up-side down-conversion in which the down-converted and fed-through frequency ranges do not overlap. No additional compensation is caused by the application of the feed-through corrector. Therefore, as is shown in FIG. 2, a signal is first converted to f−f_{LO} but appears at a frequency f. During processing the hardware system of the oscilloscope feeds through signal that is not converted at frequency f, and thus appears at frequency f+f_{LO}. In accordance with the invention, a software correction system is provided for correcting the feed-through signal that appears at frequency f+f_{LO}. As is shown in FIG. 2, this software correction is designed to offset the feed-through error generated by the hardware portion of the system. Therefore, in accordance with further operation of the software system of the oscilloscope, the software correction of the feed-through appears at frequency f+2f_{LO}. This introduces a frequency f+2f_{LO} not initially present in the signal. DSP for high image filtering, however, is preferably provided to address this issue.

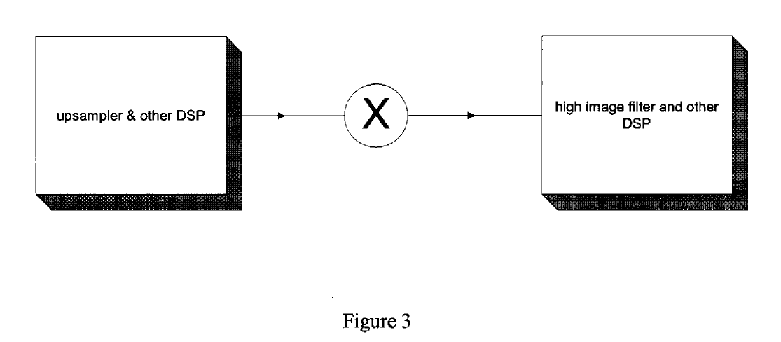

The DSP that performs Digital Bandwidth interleaving has been described extensively in various patents and patent applications noted above. At the heart of the DSP system is a software multiplier. Its purpose is to convert/shift back the frequencies that have been shifted/converted by the DBI hardware, typically a mixer. It is preceded, at a minimum, by an upsampler component, and followed, at a minimum, by a high-image filter (see FIG. 3). A more sophisticated implementation can embed various digital filters having specific functions, such as compensation for the effect of temperature change on the impulse response, and more.

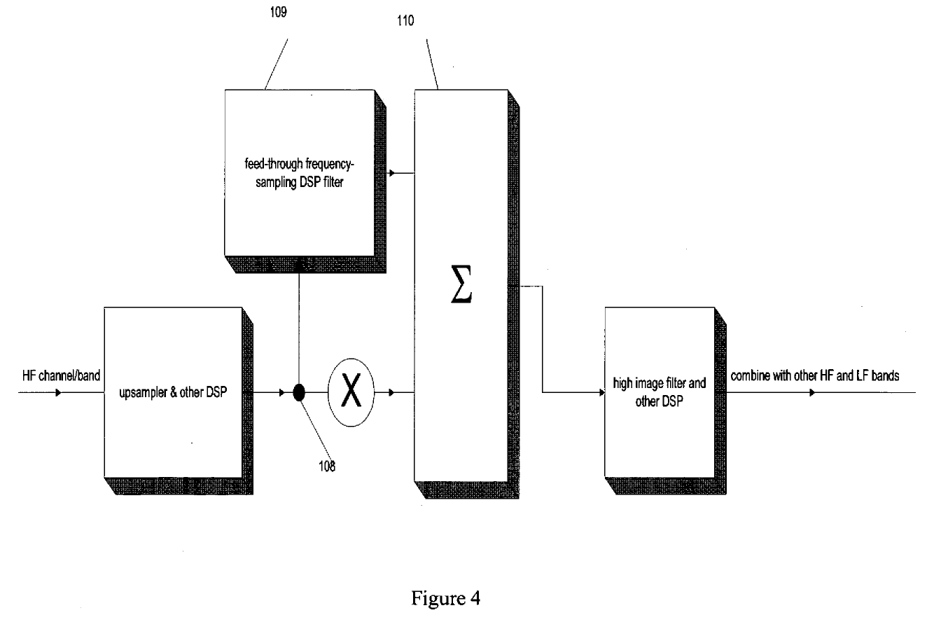

In order to implement a correction for the feed-through noted above, the design in accordance with an embodiment of the invention implements a software feed-through of sort, as shown in FIG. 4. A copy is made of the signal prior to multiplication by the software “LO” (element 108 of FIG. 4). This signal is forwarded to a filter (element 109 of FIG. 4). The purpose of this element is to mimic the hardware feed-through, with one important difference−its phase is offset by 180 degrees. This ensures that it will cancel the hardware feed-through, when it is added to the output of the multiplier by the adder (element 110 of FIG. 4).

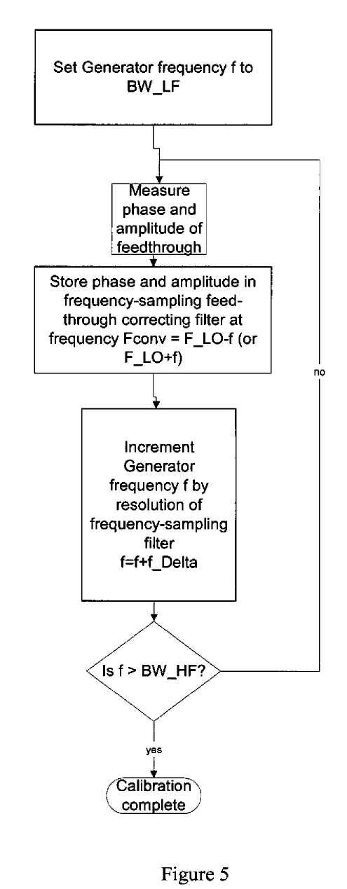

Thus, the DSP that handles the reconstruction of waveforms from several channels can handle feed-through subtraction, via a modification of the previous design of FIG. 3 design, namely the addition of a filter that bypasses the software remultiplication, and whose output is summed with the output of this remultiplication stage. For this removal of the feed-through spur to be successful, a precise measurement of the feed-through is naturally needed. A calibration algorithm used to provide this precise measurement is shown in FIG. 5.

The principle of this calibration algorithm is to operate the DBI DSP exactly as it will ultimately be used, except the taps of the software feed-through filter are all set to zero. Then, for each frequency f between BW_LF and BW_HF, the amplitude of a sine wave generator connected to the DBI input of the oscilloscope is set so that it generates an approximately 50% full scale signal on the HF channel. A Fourier transform is performed on the reconstructed waveform of the DBI scope. The complex Fourier component at frequency f, A(f), is measured. Then, the complex Fourier Component at frequency f_{LO}−F, A(f_{LO}−f), is measured. Finally, the phase phi_LO (φ_{LO}) of the software LO is established.

At the end of this loop, the ratio r=(A(f_{LO}−f)/A(f)*)e^{-iφ}^{_{LO}} (where A(f)* is the complex conjugate of the amplitude at frequency f) is available for each frequency between BW_LF and BW_HF. The Fourier transform of r (where r is zero for the frequencies not explicitly calculated) then finally constitutes the desired software feed-through corrector (called a “frequency sampling filter”).

In accordance with the invention, the following benefits, in addition to others, are achieved. First, the bandwidth of the DBI channel can reach approximately BW_LF+BW_HF even if BW_HF is larger than BW_LF. Additionally, spurs that occur at a frequency f_{LO}−f when a signal of frequency f is present can be removed by this general method if the amplitude of this spur is proportional to the amplitude of the signal AND the sum of the phase of the spur plus the phase of the signal is equal to the known phase of a reference signal of frequency f0.

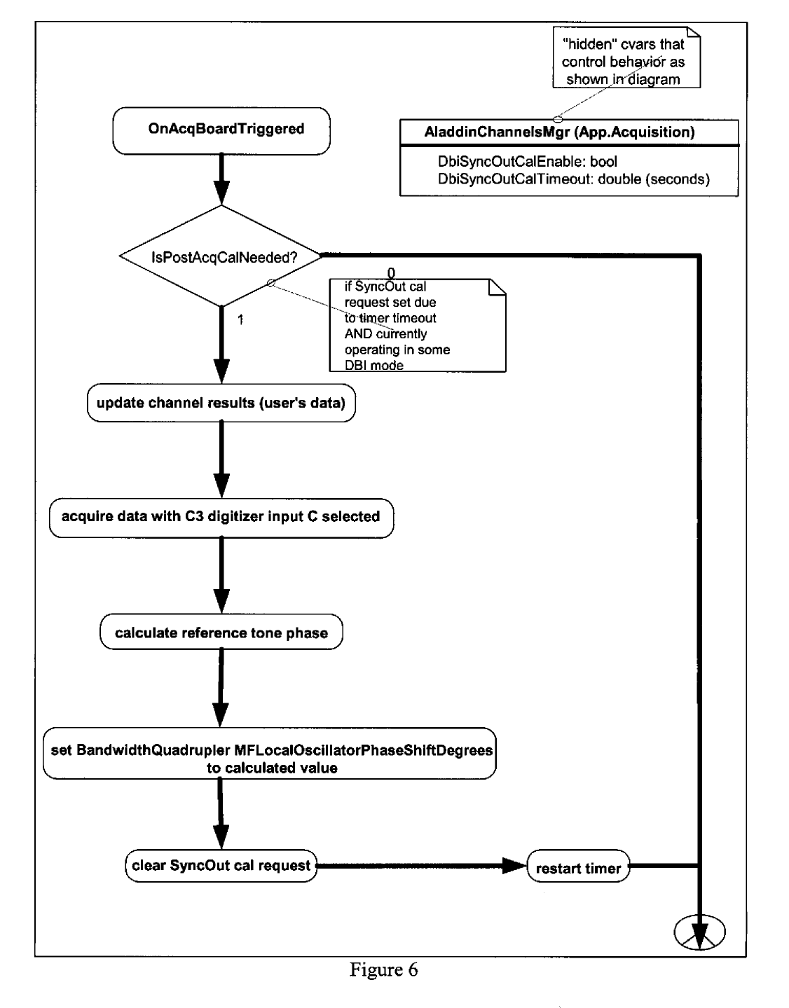

When using the system and method of the invention, the inventors have determined that phase calibration of the system is important. In accordance with the invention, a pilot tone method is preferably employed to reconstruct the phase of the mixer LO. When f_LO=˜BW_LF+BW_HF and BW_HF>BW_LF, f_LO/N is only out of the normal signal band for N=2 and for application of the pilot tone in the LF band, this solution might be adequate in certain cases. However, in some other cases, such as the preferred embodiment, the harmonics of signals in the LF band can interfere with the pilot tone. In order to avoid such a degradation of the phase accuracy of the Local Oscillator remultiplication, a dynamic calibration is developed as is shown in FIG. 6.

In such a calibration, the phase of the pilot tone is measured during a special brief calibration phase. The user signals are switched off briefly for this calibration. Over a period of time of a minute, the phase of the local oscillator remains constant. Over longer periods of time, such as hours, thermal flow changes and other phenomena can cause the phase to drift to a different value. This justifies a periodic recalibration of the phase based on the pilot tone. In the context of a digital oscilloscope, it represents a special challenge to guarantee that this phase will always be measured at a time that is less than one minute away from the time of the user acquisition. In particular, it is not an acceptable solution to perform the calibration every minute while the trigger is armed and the trigger condition is not yet met. The only way to perform the calibration is to perform an acquisition of the pilot tone, and if the trigger were to occur exactly while this acquisition takes place, it would be missed. Such a form of “dead time” is not acceptable in the oscilloscope context. To deal with this case, in accordance with the invention the method and apparatus employ a concept of an “after calibration”.

Substantially every time the acquisition either arms or triggers, a timer is consulted. If the minimum required time interval has elapsed, e.g. one minute, the calibration is performed. If an event occurs shortly after arm, this calibration will be used. If it occurs a long time after arm (e.g. more than one minute after arm), then the data just readout is temporarily stored in a buffer. Then the phase calibration is performed. Finally, the data stored in that buffer is reconstructed using the results of this “after calibration”. With this method, the most correct phase of the local oscillator is always used, whether the triggers happen quickly after arm, or whether they occur a long time after arm.

This calibration scheme differs additionally, at least in part, from more traditional calibration schemes in that more traditional calibrations have been performed as part of the arming procedure (typically calibration acquisitions/readouts are performed, followed by loading or preparing the various hardware components for the user's particular configuration, and then arming the system for further use by the user). In accordance with the invention, the “after calibration” is performed by running an acquisition with different hardware configurations (that is, different from the user's desired hardware setup) and making a measurement on the acquired data (for calibration purposes) even after the user's acquisition has triggered and processing in accordance with the user's desires have been started. This process flow thus requires the invention to store in a buffer or the like any of the user's acquired data before proceeding with a calibration acquisition. If not so performed, any data acquired in accordance with the calibration acquisition scheme would overwrite the user's data. After calibration it is then necessary to restore the user's hardware configuration so that the desired user configuration is in place when a next user acquisition is started.

Therefore, in accordance with the invention, it is possible to provide a greater bandwidth in a DBI enhanced oscilloscope using the same hardware systems, thus improving the operation thereof. While this system has been described as applicable of oscilloscopes, and other test and measurement devices, or electrical devices in general, that employ band width defined channels may similarly benefit from this invention.

It will thus be seen that the objects set forth above, among those made apparent from the preceding description, are efficiently attained and, because certain changes may be made in carrying out the above method and in the construction(s) set forth without departing from the spirit and scope of the invention, it is intended that all matter contained in the above description and shown in the accompanying drawings shall be interpreted as illustrative and not in a limiting sense.

It is also to be understood that the description and drawings are intended to cover all of the generic and specific features of the invention herein described and all statements of the scope of the invention which, as a matter of language, might be said to fall there between.

What is claimed:

1. A method for correcting feed through signals for use with an oscilloscope employing Digital Bandwidth Interleaving, comprising the steps of:
converting an original signal to a frequency other than an original frequency of the original signal;
determining one or more feed through signals not converted with the original signal;
providing an offsetting correction signal; and
combining the converted signal, the non-converted feed through signal, and the offsetting correction signal.

2. The method of claim 1, further comprising the step of compensating any amplitude modification introduced by the combining step.

3. The method of claim 2, wherein the amplitude modification compensation is frequency dependent.

4. The method of claim 1, wherein the converting of the original signal comprises a down-side down-conversion.

5. The method of claim 1, wherein the converting of the original signal comprises an up-side down conversion.

6. The method of claim 1, wherein the step of providing an offsetting correction signal further comprises the step of processing the original signal to mimic the determined one or more feed through signals, the mimicked signal having a phase offset of 180 degrees as compared with the determined one or more feed through signals.

7. The method of claim 6, further comprising the step of calibrating a processing element to mimic the determined one or more feed through signals, the mimicked one or more signals having a phase offset of 180 degrees as compared with the determined one or more feed through signals.

8. The method of claim 7, wherein the step of calibration further comprises the steps of:
operating the Digital Bandwidth Interleaved oscilloscope with taps of a software feed through filter, used to generate the mimicked feed through signals, set to zero;
scanning a plurality of predetermined frequencies within a predetermined frequency range with a sine wave generator to generate a digitized waveform at each predetermined frequency in the range, each waveform having approximately a 50% full scale signal on a channel that is to receive the signal to be converted;
performing a Fourier transform on each of the generated waveforms;
measuring a complex Fourier Component at one or more predetermined frequencies for each of the generated waveforms; and
constructing the software feed through filter.

9. The method of claim 8, wherein the software feed through filter is constructed by taking the discrete Fourier transform of the equation
r=(A(f_{LO}−f)/A(f)*)e^{-iφ}^{_{LO}}
where A is the discrete Fourier transform component of an acquired waveform, f_{LO}−f is the converted waveform frequency, f is the original frequency, and φ_{LO} is a phase adjustment applied in the conversion process.

10. The method of claim 1, wherein the step of combining is performed by linearly summing the converted signal, the non-converted feed through signal, and the offsetting correction signal.

11. The method of claim 1, further comprising the step of converting the combined converted signal back to the original frequency of the original signal.

12. A method for correcting feed through signals for use with an oscilloscope employing Digital Bandwidth Interleaving, comprising the steps of:
converting a signal having a frequency f about a frequency of a local oscillator f_{LO} to a frequency f_{LO}−f;
determining one or more feed through signals at a frequency f not converted with the signal;
providing an offsetting correction signal at frequency f; and
combining the converted signal, the non-converted feed through signal at frequency f, and the offsetting correction signal at frequency f_{LO}−f.

13. A method for correcting feed through signals for use with an oscilloscope employing Digital Bandwidth Interleaving, comprising the steps of:
converting a signal having a frequency f about a frequency of a local oscillator f_{LO} to a frequency f−f_{LO};
determining one or more feed through signals at a frequency f not converted with the signal;
providing an offsetting correction signal at frequency f; and
combining the converted signal, the non-converted feed through signal at frequency f, and the offsetting correction signal at frequency f−f_{LO}.

14. The method of claim 13, wherein a high frequency image suppression filter removes artifacts produced at f+2f_{LO}.
